(19) United States
(12) Patent Application Publication
(10) Pub. No.: US 2016/0197031 A1
(43) Pub. Date: Jul. 7, 2016

(54) SEMICONDUCTOR DEVICE, ELECTRONIC DEVICE INCLUDING THE SAME, AND METHOD OF MOUNTING SEMICONDUCTOR DEVICE

(71) Applicant: Samsung Electronics Co., Ltd., Suwon-si (KR)

(72) Inventors: Jung-Hoon KIM, Suwon-si (KR); Young-Jae KO, Hwaseong-si (KR)

(21) Appl. No.: 14/948,774

(22) Filed: Nov. 23, 2015

(30) Foreign Application Priority Data
Jan. 7, 2015 (KR) 10-2015-0002241

(51) Int. Cl. H01L 23/498; H01L 21/48

(52) U.S. Cl. CPC H01L 23/49816; H01L 23/49894; H01L 21/4853

(57) ABSTRACT

An electronic device including a semiconductor device and a method of mounting a semiconductor device are provided. The semiconductor device includes a base substrate having a semiconductor chip mounted on one surface thereof, a plurality of solder bumps arranged in a first region on another surface of the base substrate, at least one resin recess formed in a second region that is different from the first region on the other surface of the base substrate, and a bonding resin with which the at least one resin recess is filled, wherein the semiconductor device is mounted on a printed circuit board of an electronic device by a bonding resin. The semiconductor device and the electronic device including the same according to the present disclosure may be implemented in various ways according to embodiments.

### CROSS-REFERENCE TO RELATED APPLICATION(S)

This application claims the benefit under 35 U.S.C. §119(a) of a Korean patent application filed on Jan. 7, 2015 in the Korean Intellectual Property Office and assigned Serial number 10-2015-0002241, the entire disclosure of which is hereby incorporated by reference.

### TECHNICAL FIELD

The present disclosure relate to an electronic device. More particularly, the present disclosure relates to an electronic device including a semiconductor device and a method of mounting a semiconductor device.

### BACKGROUND

Currently, with the rapid development of functions and performance of electronic devices, for example mobile communication terminals, compactness and lightening the weight thereof may be required to ensure portability. Accordingly, continued progress is being made to achieve compactness of the electronic devices by raising a degree of integration of circuit devices, for example semiconductor devices, such as Application Processors (APs) or Communication Processors (CPs), which are provided to the electronic devices.

A semiconductor device may be mounted on and electrically connected to a printed circuit board through arrangement of solder bumps referred to as a ‘Ball Grid Array (BGA).’ When the BGA type semiconductor device is mounted on and secured to the printed circuit board, it may be difficult to ensure a sufficient fixing force only through the solder bumps. Therefore, while the BGA type semiconductor device is mounted on the printed circuit board, a bonding resin may be injected and applied between the semiconductor device and the printed circuit board, thereby more stably securing the semiconductor device to the printed circuit board.

A semiconductor device may be mounted on a printed circuit board through a surface mounting process. In the surface mounting process, a shield can for encapsulating the semiconductor device may also be mounted on the printed circuit board in order to suppress an effect of high-frequency noise and enhance heat dissipation efficiency.

In order to inject and apply a resin between the semiconductor device and the printed circuit board, openings may be formed for inserting a nozzle into the shield can. However, a high-frequency noise shielding effect and heat dissipation efficiency may be degraded by the openings formed in the shield can.

In cases where a plurality of semiconductor devices are arranged in one shield can, the shield can may be manufactured in a two-piece structure including a frame and a cover. When the shield can has the two-piece structure, only the frame may be mounted on a printed circuit board in a surface mounting process, and the cover may be mounted on the frame after injection and application of resin. The frame of the shield can may have frame shafts arranged therein for isolating the plurality of semiconductor devices from each other. The frame shafts may deteriorate a degree of freedom of design in the arrangement of the semiconductor devices and may be obstacles to injection and application of the resin. Therefore, sufficient gaps have to be maintained between the frame shafts and the semiconductor devices on the printed circuit board such that a nozzle for injecting and applying a resin can approach the semiconductor devices.

Therefore, a need exists for an electronic device including a semiconductor device that can be stably mounted on and secured to a printed circuit board without a process of injecting and applying a resin, and a method of mounting a semiconductor device.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide an electronic device including a semiconductor device that can be stably mounted on and secured to a printed circuit board without a process of injecting and applying a resin, and a method of mounting a semiconductor device.

Another aspect of the present disclosure is to provide an electronic device including a semiconductor device that can be easily mounted on a printed circuit board and contribute to improvement of high-frequency noise shielding and heat dissipation efficiency, and a method of mounting a semiconductor device.

In accordance with an aspect of the present disclosure, an electronic device is provided. The electronic device includes a printed circuit board and a semiconductor device mounted on the printed circuit board, wherein the semiconductor device includes a plurality of solder bumps arranged in a region on a surface thereof, a resin recess formed in another region on the surface, and a bonding resin with which the resin recess is filled.

In accordance with another aspect of the present disclosure, a method of mounting a semiconductor device on a printed circuit board of an electronic device is provided. The method includes preparing a Ball Grid Array (BGA) type semiconductor device that includes a plurality of solder bumps arranged in a first region on a surface of a base substrate, at least one resin recess formed in a second region different from the first region, and a bonding resin with which the resin recess is filled, mounting the semiconductor device on a printed circuit board, and heating at least the solder bumps while the semiconductor device is mounted on the printed circuit board, wherein the solder bumps are thermally bonded to the printed circuit board in the operation of heating the at least the solder bumps while the semiconductor device is mounted on the printed circuit board.

In accordance with another aspect of the present disclosure, an electronic device is provided. The electronic device includes a semiconductor device. The semiconductor device includes a BGA type semiconductor device that includes a plurality of solder bumps arranged in a region on a surface thereof, a resin recess formed in another region on the surface, and a bonding resin with which the resin recess is filled.

According to the embodiments of the present disclosure, in the operation of heating the at least the solder bumps while the semiconductor device is mounted on the printed circuit board (a reflow process) in which a BGA type semiconductor device is mounted on a surface of a printed circuit board and solder bumps are then thermally bonded to the printed circuit board, a base substrate can be bonded to the printed circuit board by a bonding resin with which the base substrate is filled, so that the semiconductor device can be stably mounted on and secured to the printed circuit board even without injection and application of a separate resin. In addition, according to the embodiments of the present disclosure, openings for insertion of a nozzle are not required for a shield can that is mounted on the printed circuit board together with the semiconductor device in the mounting of the semiconductor device on the printed circuit board (a surface mounting process), thereby making it possible to enhance high-frequency noise shielding and heat dissipation efficiency of the shield can. Furthermore, even though the shield can is manufactured in a two-piece structure, it is possible to easily arrange frame shafts for isolating semiconductor devices from each other.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a perspective view illustrating an electronic device including a Ball Grid Array (BGA) type semiconductor device according to various embodiments of the present disclosure;

FIG. 2 is a sectional view illustrating a semiconductor device included in an electronic device according to the various embodiments of the present disclosure;

FIG. 3 is a plan view illustrating a bottom end of a semiconductor device included in an electronic device according to the various embodiments of the present disclosure;

FIG. 4 is a plan view illustrating a bottom end of a BGA type semiconductor device according to various embodiments of the present disclosure; and

FIG. 5 is a flowchart illustrating a method of mounting a BGA type semiconductor device on an electronic device according to various embodiments of the present disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Although the terms including an ordinal number, such as first, second, and the like, can be used for describing various elements, the structural elements are not restricted by the terms. The terms are only used to distinguish one element from another element. For example, without departing from the scope of the present disclosure, a first structural element may be named a second structural element. Similarly, the second structural element also may be named the first structural element. As used herein, the term “and/or” includes any and all combinations of one or more associated items.

The relative terms, such as a front surface, a rear surface, an upper surface, and a lower surface, which are described with reference to the drawings may be replaced by ordinal numbers, such as first and second. In the ordinal numbers, such as first and second, their order are determined in the mentioned order or arbitrarily and may not be arbitrarily changed if necessary.

In the present disclosure, the terms are used to describe specific embodiments of the present disclosure, and are not intended to limit the present disclosure. As used herein, the singular forms are intended to include the plural forms as well, unless the context clearly indicates otherwise. In the description, it should be understood that the terms “include” or “have” indicate existence of a feature, a number, an operation, a structural element, parts, or a combination thereof, and do not previously exclude the existences or probability of addition of one or more another features, numeral, operations, structural elements, parts, or combinations thereof.

Unless defined differently, all terms used herein, which include technical terminologies or scientific terminologies, have the same meaning as that understood by a person skilled in the art to which the present disclosure belongs. Such terms as those defined in a generally used dictionary are to be interpreted to have the meanings equal to the contextual meanings in the relevant field of the art, and are not to be interpreted to have ideal or excessively formal meanings unless clearly defined in the present disclosure.

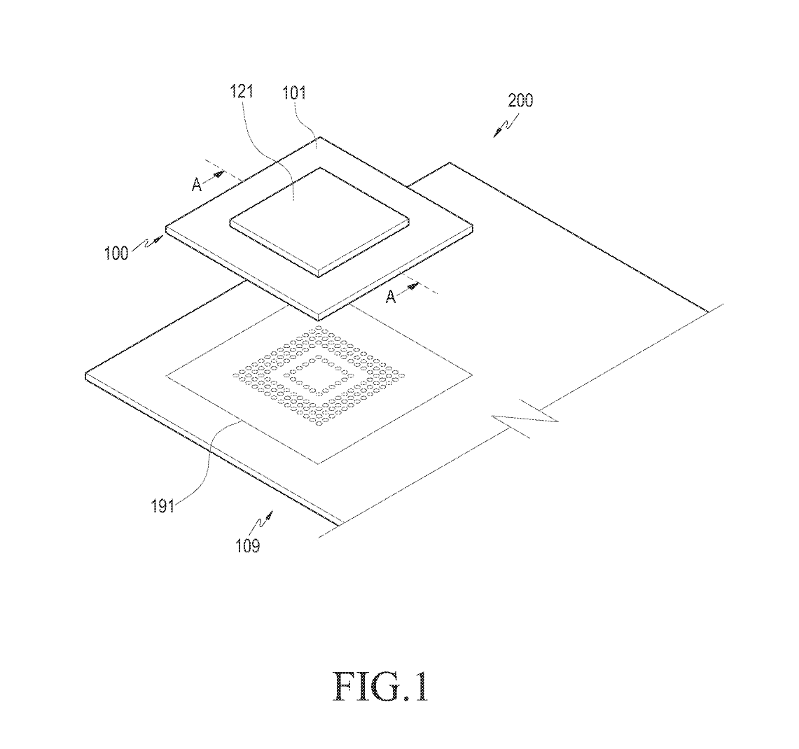

FIG. 1 is a perspective view illustrating an electronic device including a Ball Grid Array (BGA) type semiconductor device according to various embodiments of the present disclosure.

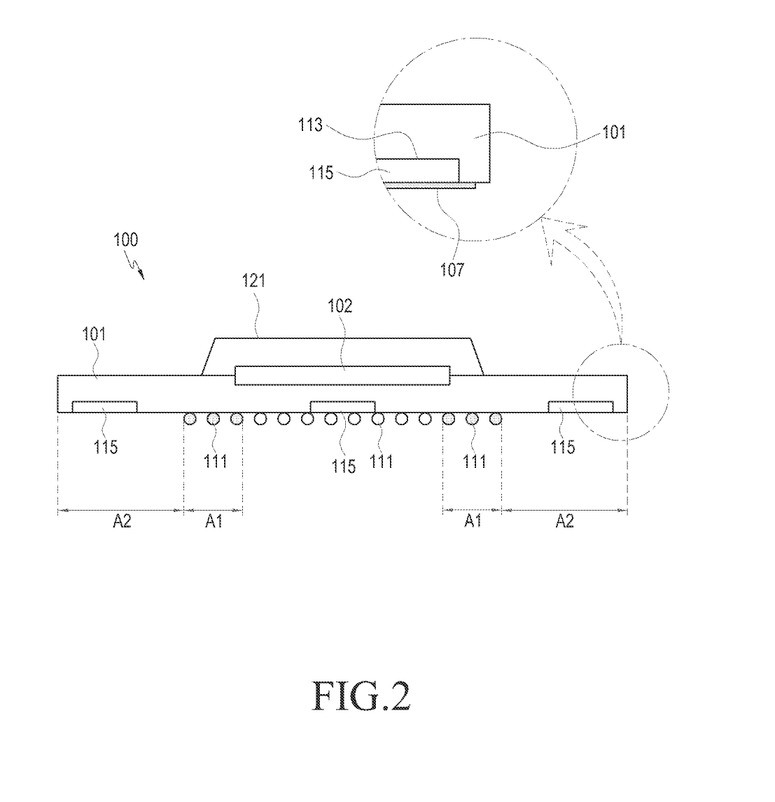

FIG. 2 is a sectional view illustrating a BGA type semiconductor device included in an electronic device according to various embodiments of the present disclosure. Referring to FIG. 2, the sectional view is taken along line A-A of FIG. 1.

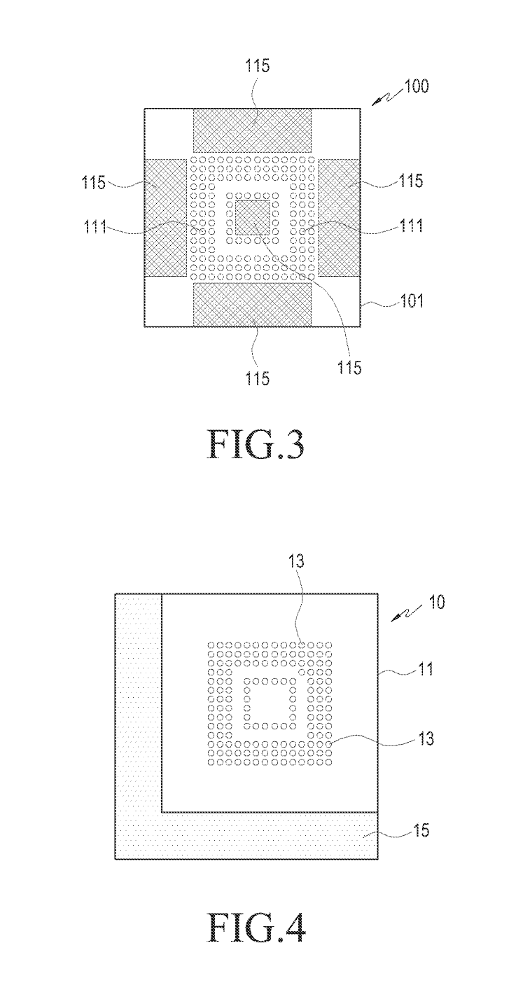

FIG. 3 is a plan view illustrating a bottom end of a BGA type semiconductor device according to the various embodiments of the present disclosure.

Referring to FIGS. 1 to 3, an electronic device 200 according to various embodiments of the present disclosure may include a printed circuit board 109 and a BGA type semiconductor device 100 (hereinafter, referred to as ‘semiconductor device’) mounted on the printed circuit board 109. The semiconductor device 100 may include a base substrate 101, a semiconductor chip 102, and a bonding resin 115. Here, the semiconductor chip may mean a semiconductor device constituting a Central Processing Unit (CPU), an Application Processor (AP), a Communication Processor (CP), diverse memory chips, and the like which are used in various types of electronic devices. The semiconductor chip 102 may be mounted on the base substrate 101 to constitute at least a part of the semiconductor device 100.

The semiconductor chip 102 may be mounted on one surface of the semiconductor device 100, for example, one surface of the base substrate 101 and protected from an external environment by an encapsulation resin 121 applied thereto. The semiconductor chip 102 may be at least partially embedded in one surface of the base substrate 101. The semiconductor device 100 may have a plurality of solder bumps 111 arranged in a first region A1 on the other surface of the semiconductor device 100, for example, the other surface of the base substrate 101. The arrangement of the solder bumps 111 may be set in various ways, and the solder bumps 111 may be connected to electrode pads provided on the base substrate 101, respectively, although not illustrated. Electrodes of the semiconductor chip 102 may be connected to electrode pads provided on the base substrate 101 through wire bonding, respectively.

The bonding resin 115 may be provided in a second region A2 which is different from the first region A1 on the other surface of the semiconductor device 100, for example, the other surface of the base substrate 101. One or more resin recesses 113 for accommodating the bonding resin 115 may be formed on one surface of the semiconductor device 100, for example, the other surface of the base substrate 101. Four resin recesses 113 around the solder bumps 111 and one resin recess 113 in the center of the base substrate 101 are exemplified in this embodiment of the present disclosure. The resin recesses 113 may be filled with the bonding resin 115 in a liquid, solid, or gel state. While the resin recesses 113 are filled with the bonding resin 115, a sealing film 107 is attached to the other surface of the base substrate 101 to seal the resin recesses 113. In an embodiment of the present disclosure, when the bonding resin 115 is in a solid state or a gel state, the sealing film 107 may not be attached to the base substrate 101.

The above-described semiconductor device 100 may be disposed and mounted on the electronic device 200, for example the printed circuit board 109, through a surface mounting process. While the semiconductor device 100 is disposed on the printed circuit board 109, the solder bumps 111 may be thermally bonded to conductive pads provided in a partial region 191 of the printed circuit board 109 through a reflow process of heating the solder bumps to a temperature of 200 to 350 degrees Celsius, for example 260 degree Celsius. Accordingly, the semiconductor device 100 may be mounted on and secured to the printed circuit board 109 and electrically connected thereto at the same time. However, in the thermal bonding of the solder bumps 111, the sealing film 107 is damaged so that the base substrate 101 may be bonded to the printed circuit board 109 by the bonding resin 115 in the liquid state. If the resin recesses 113 are filled with the bonding resin 115 in a solid state or a gel state, the bonding resin 115 dissolves in the reflow process and spreads between the base substrate 101 and the printed circuit board 109 so that the semiconductor device 100, for example the base substrate 101, may be bonded to the printed circuit board 109. After the reflow process, a curing process may be performed for curing the bonding resin 115.

When the semiconductor device 100 is mounted on the printed circuit board 109, a gap of 0.05 mm may be formed between the base substrate 101 and the printed circuit board 109. In this case, the bonding resin of 0.05 cc per unit area (mm̂2) may be provided to fill the resin recesses 113 on the other surface of the base substrate 101. For example, when the other surface of the base substrate 101 has an area of 11 mm*10 mm, the total volume of the bonding resin 115 to fill the resin recesses 113 may be about 5.5 cc. The total volume of the bonding resin 115 to fill the resin recesses 113 may be properly set in view of the size of the base substrate 101, the gap between the base substrate 101 and the printed circuit board 109, and the like.

FIG. 4 is a plan view illustrating a bottom end of a BGA type semiconductor device according to various embodiments of the present disclosure.

As described above, while a BGA type semiconductor device is mounted on a printed circuit board, the semiconductor device is secured to the printed circuit board by injecting and applying a resin.

Referring to FIG. 4, when the resin is applied to a BGA type semiconductor device 10, the resin may be additionally applied to some regions of the printed circuit board around a base substrate 11. When the semiconductor device 10 illustrated in FIG. 4 has the same specification as the aforementioned semiconductor device 100 according to the various embodiments of the present disclosure (for example, when the number and the arrangement of solder bumps thereof are the same), the resin may be additionally applied to some regions 15 of the printed circuit board around the base substrate 11 in the method of securing the semiconductor device to the printed circuit board by injecting and applying the resin. The base substrate 11 of the semiconductor device 10 may have a size of 10 mm*11 mm for arrangement of a semiconductor chip and solder bumps 13, and the bonding resin may be unnecessarily applied to the regions 15 having a width of 4 mm on a surface of the printed circuit board, in addition to the area corresponding to the base substrate 11 having the aforementioned size. For example, when it is assumed that the semiconductor devices have the same specifications, in the case of the semiconductor device 100 according to the various embodiments of the present disclosure, a bonding resin may be applied only to the base substrate 101 having the size of 10 mm*11 mm. In contrast, in the case of the semiconductor device 10 secured through injecting and applying a resin, the resin may also be applied to the regions 15 having the width of about 4 mm along a moving path of a nozzle. When the regions 15 are formed as illustrated in FIG. 4, the total area of the regions 15 is about 100 mm̂2 (4 mm*(10 mm+11 mm+4 mm)) If the thickness of the resin applied to the regions 15 around the base substrate 11 is about 0.05 mm which is the same as the gap between the base substrate 11 and the printed circuit board, the resin of about 5 cc may be substantially consumed. For example, the resin may be consumed in proportion to the total area of the regions 15 when the BGS type semiconductor device 10 is mounted on and secured to the printed circuit board.

In contrast, as described above, in the case of the semiconductor device 100 according to the various embodiments of the present disclosure, the resin recesses of the base substrate 101 may be filled with the bonding resin 115 required to bond the base substrate 101 to the printed circuit board 109, and the base substrate 101 may be easily bonded to the printed circuit board 109 by the bonding resin 115 with which the resin recesses of the base substrate 101 are filled, thereby preventing the bonding resin 115 from being unnecessarily consumed.

In addition, in the case of the electronic device 200 according to the various embodiments of the present disclosure, it is unnecessary to separately inject and apply a resin after the semiconductor device 100 is mounted on the printed circuit board so that a complete shielding structure can be achieved using a shield can. Therefore, it is possible to enhance high-frequency noise shielding and heat dissipation efficiency. Even when the shield can for shielding the semiconductor device 100 according to the various embodiments of the present disclosure has a two-piece structure including a frame and a cover, the frame of the shield can may be disposed sufficiently close to the semiconductor device 100, thereby enhancing a degree of integration of the printed circuit board 109 or a degree of freedom of design regarding the arrangement of the semiconductor device 100, the shield can, and the like.

As described above, a semiconductor device according to various embodiments of the present disclosure may include a base substrate having a semiconductor chip mounted on one surface thereof, a plurality of solder bumps arranged in a first region on the other surface of the base substrate, at least one resin recess formed in a second region that is different from the first region on the other surface of the base substrate, and a bonding resin with which the resin recess is filled.

According to various embodiments of the present disclosure, the resin recess may be filled with the bonding resin in proportion to the size and area of the other surface of the base substrate.

According to various embodiments of the present disclosure, the base substrate may be mounted on a printed circuit board, and the base substrate and the printed circuit board may be bonded and secured to each other by the bonding resin.

According to various embodiments of the present disclosure, the semiconductor device may further include a sealing film attached to the other surface of the base substrate, wherein the sealing film may be attached to the other surface of the base substrate to seal the resin recess after the resin recess is filled with the bonding resin in a liquid state.

According to various embodiments of the present disclosure, the resin recess may be filled with the bonding resin in a solid state or a gel state.

An electronic device according to various embodiments of the present disclosure may include a printed circuit board, and a semiconductor device mounted on the printed circuit board, wherein the semiconductor device may include a plurality of solder bumps arranged in a region on a surface thereof, a resin recess formed in another region on the surface, and a bonding resin with which the resin recess is filled.

According to various embodiments of the present disclosure, the semiconductor device may further include a base substrate, and the solder bumps and the resin recess may be formed on a surface of the base substrate.

According to various embodiments of the present disclosure, the resin recess may be filled with the bonding resin in proportion to the area of the surface of the semiconductor device.

According to various embodiments of the present disclosure, the semiconductor device and the printed circuit board may be bonded and secured to each other by the bonding resin.

According to various embodiments of the present disclosure, the semiconductor device may further include a sealing film attached to the surface of the semiconductor device, wherein the sealing film may be attached to seal the resin recess after the resin recess is filled with the bonding resin in a liquid state.

According to various embodiments of the present disclosure, the resin recess may be filled with the bonding resin in a solid state or a gel state.

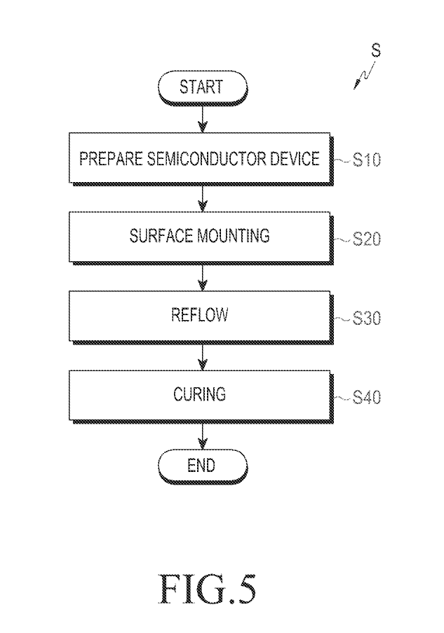

FIG. 5 is a flowchart illustrating a method of mounting a BGA type semiconductor device on an electronic device according to various embodiments of the present disclosure.

In describing a method (S) of mounting a semiconductor device according to this embodiment of the present disclosure, a description of the semiconductor device will be made with reference to the BGA type semiconductor device 100 illustrated in FIGS. 1, 2, and 3.

The semiconductor device 100 may be mounted on the partial region 191 of the printed circuit board 109 through a surface mounting process. The conductive pads corresponding to the solder bumps 111 may be arranged in the region 191 on which the semiconductor device 100 is mounted.

Referring to FIG. 5, the method (S) of mounting a BGA type semiconductor device according to the various embodiments of the present disclosure may include a preparation operation S10, a surface mounting operation S20, and a reflow operation S30 and may further include a curing operation S40 following the reflow operation S30 according to the embodiments.

The preparation operation S10 corresponds to an operation of preparing the semiconductor device 100. The semiconductor device 100 may include the plurality of solder bumps 111 arranged in the first region A1 on one surface of the base substrate 101 which has the semiconductor chip 102 mounted thereon, the one or more resin recesses 113 formed in the second region A2 which is different from the first region A1 on the surface of the base substrate 101, and the bonding resin 115 with which the resin recesses 113 are filled. For example, the preparation operation S10 may substantially correspond to an operation of manufacturing the semiconductor device 100. As described above, the resin recesses 113 may be filled with the bonding resin 115 in a liquid, solid, or gel state and then sealed by attaching the sealing film 107 when necessary.

The surface mounting operation S20 corresponds to an operation of mounting the semiconductor device 100 on the printed circuit board 109. The printed circuit board 109 may be transferred through a conveyor of surface mounting equipment, and the semiconductor device 100 may be placed on the printed circuit board 109 while the printed circuit board 109 is being transferred. A solder paste may be applied to one surface of the printed circuit board 109 transferred through the conveyor, for example the region 191 on which the semiconductor device 100 is mounted, to temporarily attach the semiconductor device 100 to the printed circuit board 109.

The reflow operation S30 corresponds to an operation of heating the solder bumps while the semiconductor device 100 is disposed and mounted on the printed circuit board 109. In this operation, the solder bumps 111 may be heated to a temperature of about 260 degrees Celsius and thermally bonded to the conductive pads arranged on the printed circuit board 109. Accordingly, the semiconductor device 100 may be secured to the printed circuit board 109. However, after the solder bumps 111 are thermally bonded, the bonding resin 115 with which the resin recesses 113 are filled may dissolve into the liquid state to spread between the base substrate 101 and the printed circuit board 109 in the reflow operation S30. If the resin recesses 113 have been already filled with the bonding resin 115 in a liquid state, the sealing film 107 may be damaged in the reflow operation S30, and the bonding resin 115 may accordingly spread between the base substrate 101 and the printed circuit board 109.

After the reflow operation S30, the base substrate 101 may be completely bonded to the printed circuit board 109 while the bonding resin 115 is being cured in a natural cooling process. If necessary, the bonding resin 115 may be cured by carrying out a forced cooling process after the reflow operation S30.

Meanwhile, the amount of the bonding resin 115 with which the base substrate 101, for example the resin recesses 113, is filled may be proportional to the size and area of the base substrate 101 and the gap between the base substrate 101 and the printed circuit board 109. For example, when the gap between the base substrate 101 and the printed circuit board 109 is 0.05 mm, a bonding resin of 0.05 cc per unit area (mm̂2) may be provided to fill the resin recesses 113 on one surface of the base substrate 101. In this case, when the surface of the base substrate 101 has an area of 110 mm̂2, the total volume of the bonding resin 115 to fill the resin recesses 113 of the base substrate 101 may be about 5.5 cc.

A method of mounting a semiconductor device on an electronic device according to various embodiments of the present disclosure may include: preparing a semiconductor device that includes a plurality of solder bumps arranged in a first region on a surface thereof, at least one resin recess formed in a second region different from the first region, and a bonding resin with which the resin recess is filled (preparation operation), mounting the semiconductor device on a printed circuit board (surface mounting operation), and heating at least the solder bumps while the semiconductor device is mounted on the printed circuit board (reflow operation), wherein the solder bumps may be thermally bonded to the printed circuit board in the reflow operation.

According to various embodiments of the present disclosure, the base substrate and the printed circuit board may be bonded to each other by the bonding resin in the reflow operation.

According to various embodiments of the present disclosure, the solder bumps may be heated to a temperature of 200 to 350 degrees Celsius in the reflow operation.

According to various embodiments of the present disclosure, the resin recess may be filled with the bonding resin in a liquid, solid, or gel state in the preparation operation.

According to various embodiments of the present disclosure, a sealing film may be attached to seal the resin recess after the resin recess is filled with the bonding resin in the preparation operation.

According to various embodiments of the present disclosure, the bonding resin in a liquid state may spread between the base substrate and the printed circuit board in the reflow operation.

According to various embodiments of the present disclosure, the method may further include curing the bonding resin in the liquid state.

According to various embodiments of the present disclosure, the resin recess may be filled with the bonding resin in proportion to the area of the base substrate and the gap between the base substrate and printed circuit board in the surface mounting operation.

As described above, in the method of mounting a BGA type semiconductor device according to the various embodiments of the present disclosure, the base substrate can be bonded to the printed circuit board in the reflow process by the bonding resin with which the base substrate is filled. Accordingly, a separate process of injecting and applying a resin is not required to stably bond the semiconductor device to the printed circuit board, thereby simplifying the process of mounting the semiconductor device on the printed circuit board.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. A Ball Grid Array (BGA) type semiconductor device comprising:
a base substrate having a semiconductor chip mounted on one surface thereof;
a plurality of solder bumps arranged in a first region on another surface of the base substrate;
at least one resin recess formed in a second region that is different from the first region on the other surface of the base substrate; and
a bonding resin with which the at least one resin recess is filled.

2. The BGA type semiconductor device of claim 1, wherein the at least one resin recess is filled with the bonding resin in proportion to a size and an area of the other surface of the base substrate.

3. The BGA type semiconductor device of claim 1,
wherein the base substrate is mounted on a printed circuit board, and
wherein the base substrate and the printed circuit board are bonded and secured to each other by the bonding resin.

4. The BGA type semiconductor device of claim 1, further comprising:
a sealing film attached to the other surface of the base substrate,
wherein the sealing film is attached to the other surface of the base substrate to seal the at least one resin recess after the at least one resin recess is filled with the bonding resin in a liquid state.

5. The BGA type semiconductor device of claim 1, wherein the at least one resin recess is filled with the bonding resin in a solid state or a gel state.

6. A method of mounting a Ball Grid Array (BGA) type semiconductor device on an electronic device, the method comprising:
preparing a semiconductor device that comprises a plurality of solder bumps arranged in a first region on a surface thereof, at least one resin recess formed in a second region different from the first region, and a bonding resin with which the resin recess is filled;
mounting the semiconductor device on a printed circuit board; and
heating at least the solder bumps while the semiconductor device is mounted on the printed circuit board,
wherein the solder bumps are thermally bonded to the printed circuit board in the reflow operation.

7. The method of claim 6, wherein the heating of the solder bumps while the semiconductor device is mounted on the printed circuit board comprises bonding the base substrate and the printed circuit board to each other by the bonding resin.

8. The method of claim 6, wherein the heating of the solder bumps while the semiconductor device is mounted on the printed circuit board comprises heating the solder bumps to a temperature of 200 to 350 degrees Celsius.

9. The method of claim 6, wherein the preparing of the semiconductor device comprises filling the at least one resin recess with the bonding resin in at least one of a liquid state, a solid state, or a gel state.

10. The method of claim 6, wherein the preparing of the semiconductor device comprises attaching a sealing film to seal the at least one resin recess after the at least one resin recess is filled with the bonding resin.

11. The method of claim 6, wherein the heating of the solder bumps while the semiconductor device is mounted on the printed circuit board comprises spreading the bonding resin in a liquid state between the base substrate and the printed circuit board.

12. The method of claim 11, further comprising:
curing the bonding resin in the liquid state.

13. The method of claim 6, wherein the mounting of the semiconductor device on the printed circuit board comprises filling the at least one resin recess with the bonding resin in proportion to an area of the base substrate and a gap between the base substrate and printed circuit board.

14. An electronic device comprising:
a printed circuit board; and
a semiconductor device mounted on the printed circuit board,
wherein the semiconductor device comprises a plurality of solder bumps arranged in a region on a surface thereof, a resin recess formed in another region on the surface, and a bonding resin with which the at least one resin recess is filled.

15. The electronic device of claim 14,
wherein the semiconductor device further comprises a base substrate, and
wherein the solder bumps and the at least one resin recess are formed on a surface of the base substrate.

16. The electronic device of claim 14, wherein the at least one resin recess is filled with the bonding resin in proportion to an area of the surface of the semiconductor device.

17. The electronic device of claim 14, wherein the semiconductor device and the printed circuit board are bonded and secured to each other by the bonding resin.

18. The electronic device of claim 14, further comprising:
a sealing film attached to the surface of the semiconductor device,
wherein the sealing film is attached to seal the at least one resin recess after the at least one resin recess is filled with the bonding resin in a liquid state.

19. The electronic device of claim 14, wherein the at least one resin recess is filled with the bonding resin in a solid state or a gel state.
